(19) United States
(12) Patent Application Publication
(10) Pub. No.: US 2005/0122161 A1
(43) Pub. Date: Jun. 9, 2005

(54) Active filter circuit using gm amplifier, and data read circuit, data write circuit and data reproducing device using the same

(76) Inventor: Takashi Fujimura, Kyoto (JP)

Correspondence Address: MATTINGLY, STANGER & MALUR, P.C.;Suite 370, 1800 Diagonal Road, Alexandria, VA, 22314, US

(21) Appl. No.: 11/000,991

(22) Filed: Dec. 2, 2004

(30) Foreign Application Priority Data
Dec. 3, 2003 (JP) 2003-404118

(51) Int. Cl. H03B 1/00

(52) U.S. Cl. 327/552

(57) ABSTRACT

The present invention comprising an active filter having a first gm amplifier, a second gm amplifier equivalent to the first gm amplifier, a band gap power source which applies a constant voltage making use of a band gap voltage to an input of the second gm amplifier and a current-voltage conversion circuit which converts an output current of the second gm amplifier into a voltage, wherein operation currents of the first and second gm amplifiers are controlled depending on the output voltage of the current-voltage conversion circuit.

### BACKGROUND OF THE INVENTION

1. Field of the Invention

The present invention relates to an active filter circuit using a gm amplifier (a trans-conductance amplifier), and a data read circuit, a data write circuit and a data reproducing device using the same and more specifically, relates to an improvement in an active filter circuit using a gm amplifier in a frequency band variable active filter circuit which is used for changing over a frequency band at the time when performing such as an n time speed reproduction and an n time speed writing with respect to a determined reproduction speed and a determined writing speed such as in an extraction circuit of data signals and a data demodulation circuit of wobble signals such as for CD, MD and DVD, and which shows a desirable temperature characteristic and permits to reduce the number of circuit elements.

2. Background Art

In recent CD-R/RW, the data writing speed is increased such as to 2 times, 4 times, 8 times, . . . . In such CD-R/RW, write data transferred from a host computer such as via a SCSI and ATPI are usually EFM-modulated and applied to a laser controller. Laser beam controlled by the laser controller for writing use is ON/OFF controlled by the EFM-modulated data and irradiated on to a predetermined truck of a CD, thereby, data writing is performed for the predetermined truck.

Other than such CD-R/RW, in an optical disk such as CD-R and DVD-RAM, grooves are formed in a zigzag manner, thereby, such as synchronizing information for rotation control and address information (absolute time information) are recorded in a form of wobble signals.

A wobble signal is a signal, which is FSK-modulated with a modulation signal BIDATA of bi-phase code, and when the disk rotation is at a determined linear speed, the wobble frequency assumes 22.05±1 kHz (when reproducing at 1 time speed). ATIP (Absolute Time In Pre-groove) signals containing the absolute time information which is data-reproduced from the wobble signals are constituted by a synchronizing signal, address data (absolute time data) and an error detection signal CRC as a BIDATA, and usually use 42 bits as a unit thereof. Further, 75 Hz is used as a repetition frequency of the synchronizing signal.

When reproducing such data recorded on the optical disk as in a form of the wobble signals, a demodulation circuit having an active filter for demodulating data in wobble signals is required. An optical disk device using this sort of demodulation circuit is known and disclosed in JPH9-297969A or JPH11-16291A.

For extracting this sort of data other than such wobble signals, a variable gm amplifier is used as the active filter circuit. FIG. 5 shows an example of such active filter circuits.

An active filter circuit 10 is formed by a gm-C filter circuit 11 and a frequency band setting signal generation circuit 12.

The gm·C filter circuit 11 is an integrating circuit formed by a gm amplifier 11a and a capacitor C and usually constitutes a low pass filter. Further, in order to constitute a band pass filter, it is required to connect a differentiating circuit (a high pass filter (HPF)) formed by a gm amplifier 11a and a capacitor Ca at the front stage or the back stage thereof. In case of the differentiating circuit, difference is that only the capacitor is inserted at the input side of the gm amplifier and the circuit of the gm amplifier is substantially the same.

In order to simplify the description, an example of the low pass filter will be explained herein below.

To (+) input (positive phase input or non-inverted input) terminal (herein below called as (+) input) and (−) input (opposite phase input or inverted input) terminal (herein below (−) input) of the gm amplifier 11a, for example, read out signals such as wobble signals are applied from a signal source 20 such as for a read out amplifier as a differential input. The capacitor C is connected at the output side of the gm amplifier 11a to form the low pass filter (LPF) and the output thereof is obtained from an output terminal 11c. Further, 11b is a current source (an operation current source) for setting an operation current for the gm amplifier 11a.

The frequency band setting signal generation circuit 12 sets a cut off frequency of the low pass filter at a predetermined value by controlling the current value of the operation current source 11b. At the same time by setting a cut off frequency of a high pass filter (not shown) of the differentiating circuit formed by the gm amplifier 11a and the capacitor Ca at the front stage or the back stage, a frequency band of the band pass filter is set. The gm amplifier 11a is an R (resistor) simulation circuit and the resistance value of the R to be simulated varies depending on the current value of the operation current source 11b in the gm amplifier 11a. Thereby, a CR filter circuit is simulated.

Thus the frequency band setting signal generation circuit 12 is for selecting the resistance value of the simulation resistor by setting the resistance value of the operation current source 11b at a selected constant value. Thereby, the cut off frequency of the low pass filter is determined in relation to the capacitance of the capacitor C (or/and the capacitor Ca).

The frequency band setting signal generation circuit 12 is constituted by a first low pass filter circuit 13, a first buffer amplifier (a voltage follower) 14, a second low pass filter circuit 15, a second buffer amplifier (a voltage follower) 16, a multiplication circuit 17, a low pass filter (LPF) 18 and a voltage-current (V-I) conversion circuit 19. The (−) input sides of the amplifiers in the respective circuits are respectively connected each other and the output of the second buffer amplifier 16 is fed back to (−) input side of the low pass filter circuit 13 as a signal having opposite phase.

The first low pass filter circuit 13 is constituted by a gm amplifier 13a having an equivalent characteristic as the gm amplifier 11a, a capacitor C1 and an operation current source 13b for the gm amplifier 13a. The first low pass filter 13 is an equivalent circuit as the gm·C filter circuit 11. Reference clocks CLK from such as an oscillation circuit and divided via such as a divider circuit (not shown) are received from an input terminal 12a at (+) input side of the gm amplifier 13a. The output of the low pass filter circuit 13 is applied to (+) input of the first buffer amplifier 14. The output of the first buffer amplifier 14 is sent out to (+) input of the second low pass filter circuit 15.

The second low pass filter circuit 15 is constituted by a gm amplifier 15a having an equivalent characteristic as the gm amplifier 11a, a capacitor C2 and an operation current source 15b for the gm amplifier 15a. The second low pass filter 15 is also an equivalent circuit as the gm·C filter circuit 11. The output of the low pass filter circuit 15 is sent out to (+) input of the second buffer amplifier 16. The output of the second buffer amplifier 16 is sent out to the multiplication circuit 17.

The multiplication circuit 17 receives the clocks CLK inputted from the input terminal 12a at (−) input thereof, performs phase comparison between reference clocks CLK of which phase is deviated by 180° via the first and second low pass filter circuits 13 and 15 and the original reference clocks CLK and generates a voltage output corresponding to the phase deviation amount of the clocks CLK. The voltage output is received at the low pass filter (LPF) 18 wherein the voltage depending on the deviation amount is obtained as an integrating value and the integrated voltage is converted into a current value by the V-I conversion circuit 19. The frequency band setting signal generation circuit 12 performs a negative feed back control in a direction so as not to generate a phase deviation between the reference clocks CLK of which phase is deviated by 180° and the original reference clocks CLK by controlling respectively the current values of the operation current sources 13b and 15b in the respective gm amplifiers depending on the converted current value.

Thereby, a control current value for a frequency corresponding to the reference clocks CLK is generated at the frequency band setting signal generation circuit 12, the respective operation current sources 11b, 13b and 15b in the three gm amplifiers of equivalent circuits are controlled and the cut off frequency of the gm·C filter circuit 11 is set at a determined value. Accordingly, the selection of the cut off frequency of the gm·C filter circuit 11 is performed either by selecting the frequency of the reference clocks CLK or changing over thereof.

In the above referred to circuit, in order to set the frequency accurately, the frequency band setting signal generation circuit 12 requires to be provided with two gm·C filter circuits equivalent to the gm·C filter circuit 11, two buffer amplifiers and a multiplication circuit belonging thereto, through which a desirable temperature characteristic and a highly accurate frequency band selection are achieved. However, the circuit requires many number of circuit elements for constituting the same. Moreover, for the respective elements a pairing property is required and depending on the many number of the elements, a large occupation area is required when forming the active filter circuit into an IC, which are drawbacks.

### SUMMARY OF THE INVENTION

An object of the present invention is to resolve such drawbacks of the conventional art and to provide an active filter circuit using a gm amplifier, which shows a desirable temperature characteristic and permits to reduce the number of circuit elements thereof.

Another object of the present invention is to provide a data read circuit, a data write circuit or a data reproducing device having an active filter circuit using a gm amplifier, which shows a desirable temperature characteristic and permits to reduce the number of circuit elements thereof.

An active filter circuit according to a first aspect of the present invention which achieves the above objects comprises an active filter having a first gm·amplifier, a second gm amplifier equivalent to the first gm amplifier, a band gap power source which applies a constant voltage making use of a band gap voltage to an input of the second gm amplifier and a current-voltage conversion circuit which converts an output current of the second gm amplifier into a voltage, wherein operation currents of the first and second gm amplifiers are controlled depending on the output voltage of the current-voltage conversion circuit.

An active filter circuit according to a second aspect of the present invention further comprises a voltage-current conversion circuit which converts the output voltage of the current-voltage conversion circuit into current, wherein the operating currents of the gm amplifiers are controlled depending on the output current of the voltage-current conversion circuit.

As will be seen from the above, according to the present invention, a current substantially independent from temperature is produced in the gm amplifier equivalent to the gm amplifier in the active filter circuit by making use of the band gap power source and the produced voltage is converted by the current-voltage conversion circuit into a voltage value which causes to generate an operating current corresponding to a cut off frequency of the active filter circuit. Then, the operating current of the gm amplifier in the active filter circuit is controlled depending on the output voltage of the current-voltage conversion circuit.

Thereby, without receiving the reference clocks CLK as well as without necessitating many numbers of circuits such as a plurality of gm amplifiers and buffer amplifiers and a phase comparison circuit, a stable filter having a desirable temperature characteristic can be manufactured. Accordingly, when the active filter circuit is formed into an IC, the occupation area can be reduced. Further, the selection of the cut off frequency of the active filter circuit can be easily performed by selecting the conversion rate of the current-voltage conversion circuit. Namely, the cut off frequency can be selected, for example, by using a variable resistor or a variable constant voltage circuit to be externally attached to an IC as the current-voltage conversion circuit.

As a result, an active filter circuit using a gm amplifier, which shows a desirable temperature characteristic and permits to reduce the number of circuit elements can be easily realized. Further, a data read circuit, a data write circuit and a data reproducing device having an active filter circuit using a gm amplifier also enjoy the same advantages as above.

### BRIEF DESCRIPTION OF THE DRAWINGS

FIG. 1 is a block diagram of one embodiment to which an active filter circuit using a gm amplifier according to the present invention is applied;

FIG. 2 is a block diagram of another embodiment;

FIG. 3 is a block diagram of still another embodiment;

FIG. 4 is a block diagram of a further embodiment; and

FIG. 5 is a view for explaining an example of conventional active filter circuits.

### DESCRIPTION OF THE PREFERRED EMBODIMENTS

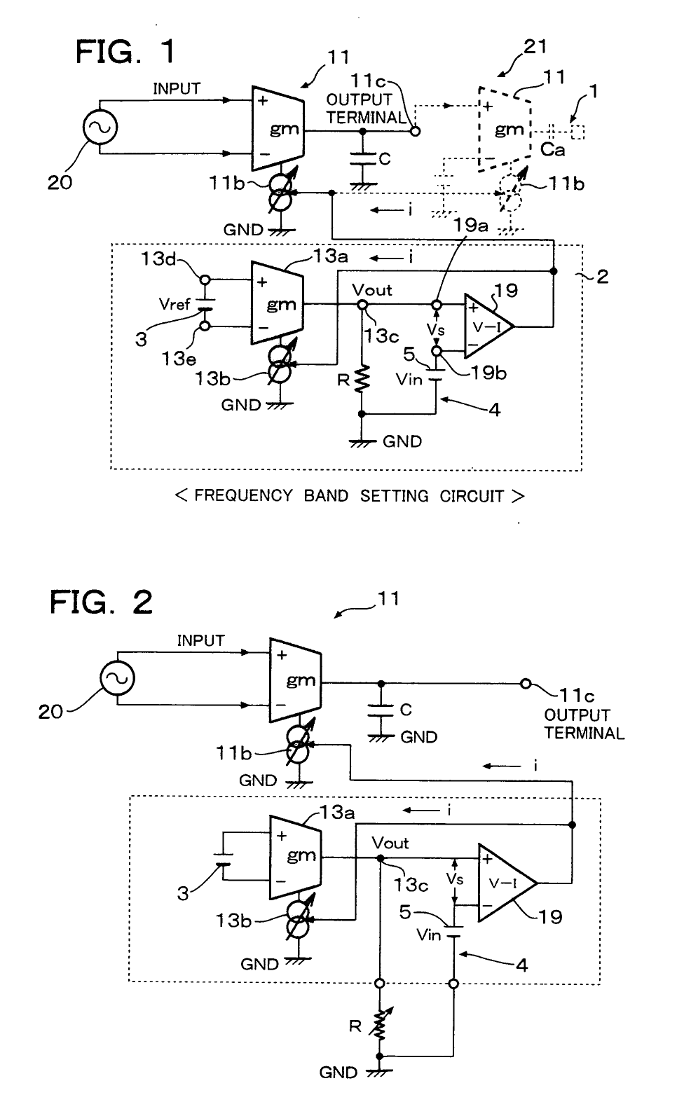

In FIG. 1, 1 is an active filter circuit and is formed by a gm·C filter circuit 11 and a frequency band setting signal generation circuit 2. Further, throughout the entire drawings, same reference numerals are assigned for the same or equivalent constitutional elements and duplicate explanation of the same or equivalent constitutional elements is omitted.

The frequency band setting signal generation circuit 2 is constituted by a band gap power source (a constant voltage circuit is acceptable) 3 which generates as a power source voltage a constant voltage by making use of a band gap voltage of a forward direction diode characteristic, a gm amplifier 13a, a current-voltage conversion circuit 4 and a voltage-current (V-I) conversion circuit 19. The band gap power source 3 is inserted between (+) input terminal 13d and (−) input terminal 13e of the gm amplifier 13a and applies a reference voltage Vref between the (+) input terminal 13d and the (−) input terminal 13e. The current-voltage conversion circuit 4 is constituted by a resistor R and a constant voltage circuit 5, and the resistor R is connected between an output terminal 13c of the gm amplifier 13a and the ground GND. The current-voltage conversion circuit 4 converts the output current of the gm amplifier 13a into a voltage. A constant voltage circuit 5 generates a constant voltage Vin, and is connected between the ground GND and (−) input terminal 19b of the voltage-current (V-I) conversion circuit 19.

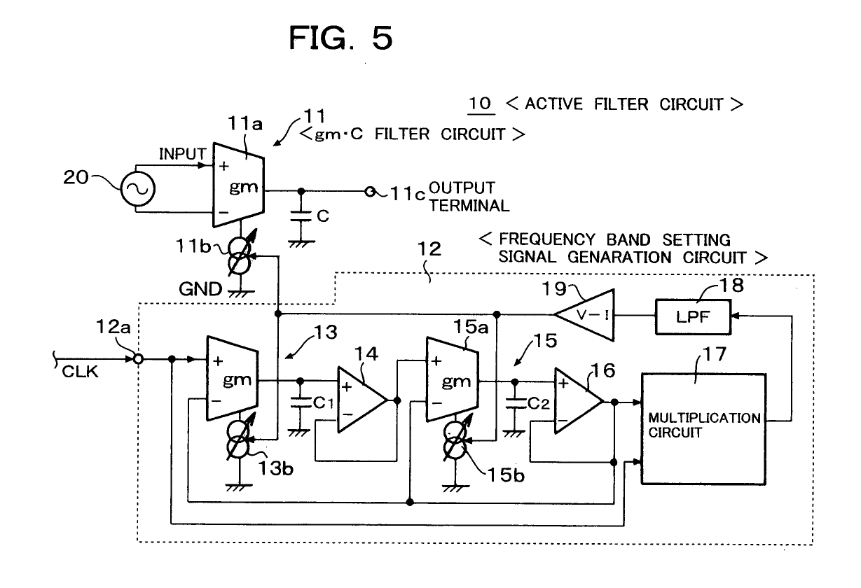

Then, an output terminal 13c of the gm amplifier 13a is connected to (+) input terminal 19a of the voltage-current (V-I) conversion circuit 19. Herein, the capacitor C1 in FIG. 5 is eliminated. Therefore, the voltage applied between the (+) input terminal 19a and the (−) input terminal 19b of the voltage-current (V-I) conversion circuit 19 corresponds to a voltage value obtained by subtracting the constant voltage Vin from the terminal voltage Vout of the resistor R.

Herein, the output current of the gm amplifier 13a is one that the reference voltage Vref of the band gap power source 3 is converted into a current value and since the voltage is the constant voltage making use of the band gap voltage, the voltage shows a constant voltage substantially not being affected by temperature. Accordingly, the output current of the gm amplifier 13a also gives a constant current not being affected by temperature. As a result, the voltage Vout generated by converting the current with the resistor R also shows the same property.

Herein, when assuming the current value for controlling the cut off frequency of the gm·C filter circuit 11 is i, and an input voltage value to be converted (conversion voltage value) prior to the V-I conversion for generating the current value i, the following equation stands;
Vs=Vout−Vin (1)

Accordingly, through selecting the terminal voltage Vout of the resistor R in the current-voltage conversion circuit 4 and the constant voltage Vin of the constant voltage circuit 5, the gm·C filter circuit 11 gives a filter circuit having a determined cut off frequency and without being affected by temperature. In other words, in the present embodiment, the resistance value of the resistor R in the current-voltage conversion circuit 4 and the constant voltage value Vin of the constant voltage circuit 5 are selected in response to the cut off frequency of the gm·C filter circuit 11.

Further, gm for the gm amplifier 13a is expressed as follows, wherein R is a resistance value of the resistor R;
gm=1/R·Vin/Vref (2)

Now, when a variable resistor is used for the resistor R in FIG. 1, the current value i for the control current can be adjusted and selected. Thereby, the cut off frequency of the gm·C filter circuit 11 can be selected.

A differentiating circuit formed by a gm·C filter circuit 11 and a capacitor Ca shown by dotted lines in the drawing constitutes a high pass filter 21. As shown in the drawing, by cascade connecting the high pass filter 21 to the active filter circuit 10, a band pass filter is given. Through controlling the current source 11b of the high pass filter 21 and the current source 11b of the active filter circuit 10 at the same time, the frequency band of the band pass filter can be set at a predetermined value. Further, such as when a variable resistor is used for the resistor R and when the voltage Vin of the constant voltage circuit 5 is made variable, which will be explained later, the frequency band of the band pass filter can be selected. Such band pass filter can be used for the data read device or the data write device.

FIG. 2 shows another embodiment in which the resistor R in FIG. 1 is modified as an externally attached one and variable. An explanation of the operation is omitted.

The feature of FIG. 2 active filter circuit is that, by modifying the resistor R as externally attached one and variable, a dispersion of the circuit characteristic can be adjusted by the variable resistor. Thereby, a dispersion in the filter characteristic by product by product can be absorbed. Of course, not by using the variable resistor but simply using an externally attached non-variable resistor, and selecting respectively the resistance value for product by product, the dispersion can be adjusted. Alternatively, by selecting the resistance value of the externally attached resistor R the cut off frequency of the gm·C filter circuit 11 can be selected.

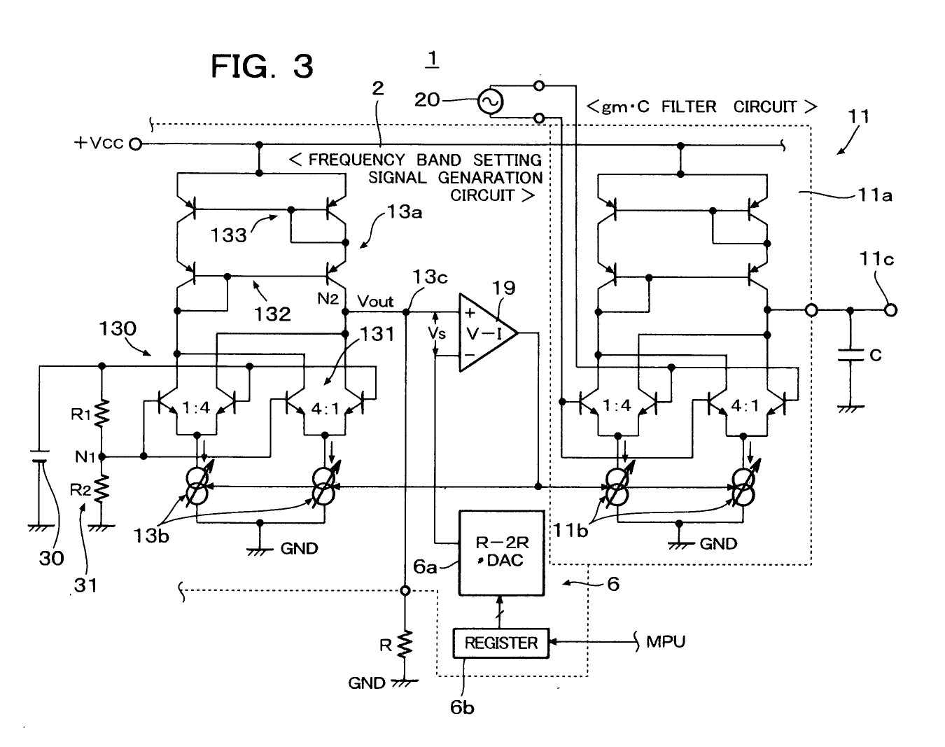

In FIG. 3, in place of the variable resistor in FIG. 2, simply an externally attached non-variable resistor is used and the constant voltage circuit 5 is replaced by a variable constant voltage generation circuit 6 in which the voltage value Vin is made variable.

In the present embodiment, FIG. 1 band gap power source 3 is modified to a band gap power source circuit and is constituted by a band gap power source voltage generation circuit 30 and a voltage dividing resistor circuit 31. Using a connection point N1 of resistors R1 and R2 in the voltage dividing resistor circuit 31, the reference voltage Vref is generated as the terminal voltage of the resistor R1.

A gm amplifier 13a is a variable gm amplifier constituted by differential amplifiers 130 and 131 connected in two stages. The differential inputs of the differential amplifiers 130 and 131 respectively receive the reference voltage Vref. The differential amplifiers 130 and 131 include current mirror circuits 132 and 133 representing a common active load. The current mirror circuits 132 and 133 are piled up in two stages at the power source line side and connected in cascade. Further, emitter area ratios (or number of connected cells) of the differential transistors in the differential amplifiers 130 and 131 are respectively designed at 1:4 and 4:1.

The gm amplifier 11a in the gm·C filter circuit 11 as shown at the right side of the drawing is the same circuit as that of the gm amplifier 13a.

The output of the differential amplifier 130 is taken out from the connection point N2 between the output side transistor of the current mirror circuit 132 and one of the differential transistors and is applied to (+) input terminal 19a of the voltage-current (V-I) conversion circuit 19.

The variable constant voltage generation circuit 6 for generating the variable voltage value Vin is constituted by a ladder type D/A conversion circuit (R-2R DAC) 6a and a register 6b, data such as from MPU are set at the register 6b and through D/A converting the set data with the R-2R·DAC 6a, the voltage value Vin is generated depending on the set data, which constitute a programmable constant voltage generation circuit.

The voltage value Vin in this instance is generated by providing the data setting the cut off frequency of the gm·C filter circuit 11 at the register 6b. Thereby, the cut off frequency of the gm·C filter circuit 11 is selected. Namely, the gm·C filter circuit 11 operates as a variable filter.

Now, when resistors having a same resistance value are used for the resistor R1 in the voltage dividing resistor circuit 31 for generating the reference voltage Vref and for the respective resistors of R-2R constituting the ladder type D/A conversion circuit 6a and an IC is formed using such resistors having a high pairing property, a characteristic dispersion of the respective filter circuits can be reduced.

Further, although the resistor R is a non-variable resistor, the resistor can of course be modified into a fixed resistor as shown in FIG. 2. Still further, the variable constant voltage generation circuit 6 can be modified into the constant voltage generation circuit 5, if the variable constant voltage generation circuit 6 is provided in series at the side of the modified variable resistor R. Namely, the circuit for generating the input voltage value Vs can be constituted by the variable resistor R and the constant voltage generation circuit, which applies a constant voltage to the terminal of the variable resistor R.

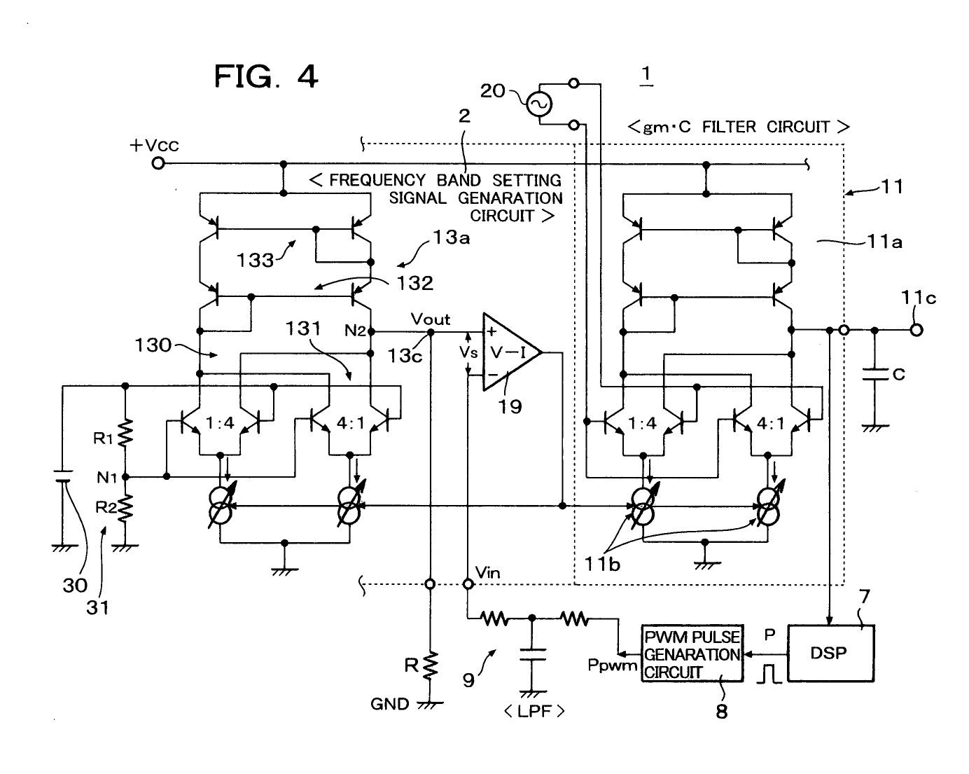

FIG. 4 is an embodiment when such as wobble signals read out from an optical disk (such as CD and DVD) are extracted, and shows a data write circuit or a data read circuit in which the cut off frequency of the filter is selected in a range of 3T˜11T in response to the multiplication number (2 times, 4 times, 8 times, . . . ) of data writing speed. Further, an illustration of the high pass filter to be cascade connected is omitted.

A part of the signals output at the output terminal 11c of the gm·C filter circuit 11 is input to a DSP (digital signal processor) 7 and pulse signals P corresponding to the multiplication number of the writing speed are produced. By inputting the pulse signals P to a PWM pulse generation circuit 8, PWM pulses Ppwm corresponding to the multiplication number of the writing speed are generated, which are inputted into a T type LPF 9 and integrated and divided therein, and the voltage value Vin corresponding to the multiplication number of the data writing speed is generated.

Thereby, the voltage value Vin corresponding to the multiplication number (2 times, 4 times, 8 times, . . . ) of the data writing speed is obtained, and the value of cut off frequency of the gm·C filter circuit 11 corresponding to the multiplication number (2 times, 4 times, 8 times, . . . ) of the data writing speed is set. In this instance, the cut off frequency of the high pass filter not shown is simultaneously set.

As has been explained hitherto, in the above embodiments, although an example is given in which the conversion voltage Vs is determined by subtraction with respect to the terminal voltage of the resistor R according to Vs=Vout−Vin, the conversion voltage Vs can of course determined by addition according to Vs=Vout+Vin. An example in which the constant voltage generation circuit is provided in series at the side of the variable resistor R as mentioned above corresponds to the above modification. Further, the above modification can be realized by inverting +pole and −pole of the constant voltage of the constant voltage circuit 5 in FIG. 1.

Further, in the above embodiments, although the control current value is obtained by converting the voltage value of the current-voltage conversion circuit 4 with the voltage-current (V-I) conversion circuit 19, the operation current of the gm amplifier can be voltage controlled by the voltage value of the current-voltage conversion circuit 4 via such as a buffer amplifier.

Still further, although the frequency band setting signal generation circuit 2 in the embodiments performs the control of setting the cut off frequency of the LPF (low pass filter), by cascade connecting the high pass filter at the front stage or the back stage of the same as shown by dotted lines in FIG. 1 and simultaneously controlling the operation current source of the gm amplifier for the HPF with the output current of the voltage-current (V-I) conversion circuit 19, the entirety can of course be constituted as a band pass filter.

Further, the gm amplifier in FIGS. 3 and 4 embodiments is only an example, a variety of gm amplifier circuits can be used therefor.

1. An active filter circuit using a gm amplifier comprising an active filter having a first gm amplifier, a second gm amplifier equivalent to the first gm amplifier, a band gap power source which applies a constant voltage making use of a band gap voltage to an input of the second gm amplifier and a current-voltage conversion circuit which converts an output current of the second gm amplifier into a voltage, wherein operation currents of the first and second gm amplifiers are controlled depending on the output voltage of the current-voltage conversion circuit.

2. The active filter circuit using a gm amplifier according to claim 1, further comprising a voltage-current conversion circuit which converts the output voltage of the current-voltage conversion circuit into current, wherein the operating currents of the first and second gm amplifiers are controlled depending on the output current of the voltage-current conversion circuit.

3. An active filter circuit using a gm amplifier comprising an active filter having a first gm amplifier with a (+) input and a (−) input, a second gm amplifier equivalent to the first gm amplifier, a band gap power source which applies a constant voltage making use of a band gap voltage between a (+) input and a (−) input of the second gm amplifier, a current-voltage conversion circuit which converts an output current of the second gm amplifier into a voltage and a voltage-current conversion circuit which converts the output voltage of the current-voltage conversion circuit into current, wherein the operating currents of the first and second gm amplifiers are set depending on the output current of the voltage-current conversion circuit.

4. The active filter circuit using a gm amplifier according to claim 3, wherein the current-voltage conversion circuit includes a resistor which receives the output current of the second gm amplifier and generates a predetermined voltage, and generates a conversion voltage corresponding to the operation current for functioning the active filter as a filter having a predetermined cut off frequency depending on a terminal voltage of the resistor.

5. The active filter circuit using a gm amplifier according to claim 4, further comprising first and second capacitors, wherein the band gap power source is a constant voltage circuit which generates a constant voltage by making use of a band gap voltage of a forward direction diode characteristic, the first gm amplifier is provided in a plurality of numbers, one of the plurality of numbers of the gm amplifiers and the first capacitor constitutes an integrating circuit, another of the plurality of numbers of the gm amplifiers and the second capacitor constitutes a differentiating circuit, the active filter is constituted by the integrating circuit and the differentiating circuit connected in cascade, the voltage-current conversion circuit includes a (+) input and a (−) input, and the current-voltage conversion circuit further includes a constant voltage circuit which generates a predetermined voltage to be added or subtracted to and from the terminal voltage and outputs between the (+) input and the (−) input of the voltage-current conversion circuit a voltage obtained by adding or subtracting the predetermined voltage with respect to the terminal voltage of the resistor as the conversion voltage.

6. The active filter circuit using a gm amplifier according to claim 5, wherein the resistor is a variable resistor and the resistance value of the variable resistor is selected so that the active filter gives the predetermined cut off frequency.

7. The active filter circuit using a gm amplifier according to claim 5, wherein the constant voltage circuit is a programmable constant voltage generation circuit which receives data external from the circuit and generates a constant voltage depending on the data.

8. A data read circuit including an active filter having a first gm amplifier and a capacitor and a setting signal generation circuit which sets a cut off frequency of the active filter at a predetermined value by controlling an operation current of the first gm amplifier, wherein the setting signal generation circuit comprises a second gm amplifier equivalent to the first gm amplifier, a band gap power source which applies a constant voltage making use of a band gap voltage to an input of the second gm amplifier and a current-voltage conversion circuit which converts an output current of the second gm amplifier into a voltage, and wherein operation currents of the first and second gm amplifiers are controlled depending on the output voltage of the current-voltage conversion circuit.

9. The data read circuit according to claim 8, wherein the setting signal generation circuit further comprises a voltage-current conversion circuit which converts the output voltage of the current-voltage conversion circuit into current, and wherein the operating currents of the first and second gm amplifiers are controlled depending on the output current of the voltage-current conversion circuit.

10. A data read circuit including an active filter having a first gm amplifier and a capacitor and a setting signal generation circuit which sets a cut off frequency of the active filter at a predetermined value by controlling an operation current of the first gm amplifier, wherein the first gm amplifier includes a (+) input and a (−) input and the setting signal generation circuit comprises a second gm amplifier equivalent to the first gm amplifier, a band gap power source which applies a constant voltage making use of a band gap voltage between a (+) input and a (−) input of the second gm amplifier, a current-voltage conversion circuit which converts an output current of the second gm amplifier into a voltage and a voltage-current conversion circuit which converts the output voltage of the current-voltage conversion circuit into current, wherein the operating currents of the first and second gm amplifiers are set depending on the output current of the voltage-current conversion circuit.

11. The data read circuit according to claim 10, wherein the current-voltage conversion circuit includes a resistor which receives the output current of the second gm amplifier and generates a predetermined voltage, and generates a conversion voltage corresponding to the operation current for functioning the active filter as a filter having a predetermined cut off frequency depending on a terminal voltage of the resistor.

12. The data read circuit according to claim 10, wherein the voltage-current conversion circuit includes a (+) input and a (−) input, and the current-voltage conversion circuit further includes a constant voltage circuit which generates a predetermined voltage to be added or subtracted to and from the terminal voltage and outputs between the (+) input and the (−) input of the voltage-current conversion circuit a voltage obtained by adding or subtracting the predetermined voltage with respect to the terminal voltage of the resistor as the conversion voltage.

13. The data read circuit according to claim 12, further comprising first and second capacitors, wherein the first gm amplifier is provided in a plurality of numbers, one of the plurality of numbers of the gm amplifiers and the first capacitor constitutes an integrating circuit, another of the plurality of numbers of the gm amplifiers and the second capacitor constitutes a differentiating circuit, the active filter is constituted by the integrating circuit and the differentiating circuit connected in cascade, the voltage-current conversion circuit includes a (+) input and a (−) input, and the current-voltage conversion circuit further includes a constant voltage circuit which generates a predetermined voltage to be added or subtracted to and from the terminal voltage and outputs between the (+) input and the (−) input of the voltage-current conversion circuit a voltage obtained by adding or subtracting the predetermined voltage with respect to the terminal voltage of the resistor as the conversion voltage.

14. A data write circuit including an active filter having a first gm amplifier and a capacitor and a setting signal generation circuit which sets a cut off frequency of the active filter at a predetermined value by controlling an operation current of the first gm amplifier, wherein the setting signal generation circuit comprises a second gm amplifier equivalent to the first gm amplifier, a band gap power source which applies a constant voltage making use of a band gap voltage to an input of the second gm amplifier and a current-voltage conversion circuit which converts an output current of the second gm amplifier into a voltage, and wherein operation currents of the first and second gm amplifiers are controlled depending on the output voltage of the current-voltage conversion circuit.

15. The data write circuit according to claim 14, wherein the setting signal generation circuit further comprises a voltage-current conversion circuit which converts the output voltage of the current-voltage conversion circuit into current, and wherein the operating currents of the first and second gm amplifiers are controlled depending on the output current of the voltage-current conversion circuit.

16. A data write circuit including an active filter having a first gm amplifier and a capacitor and a setting signal generation circuit which sets a cut off frequency of the active filter at a predetermined value by controlling an operation current of the first gm amplifier, wherein the first gm amplifier includes a (+) input and a (−) input and the setting signal generation circuit comprises a second gm amplifier equivalent to the first gm amplifier, a band gap power source which applies a constant voltage making use of a band gap voltage between a (+) input and a (−) input of the second gm amplifier, a current-voltage conversion circuit which converts an output current of the second gm amplifier into a voltage and a voltage-current conversion circuit which converts the output voltage of the current-voltage conversion circuit into current, wherein the operating currents of the first and second gm amplifiers are set depending on the output current of the voltage-current conversion circuit.

17. The data write circuit according to claim 16, wherein the current-voltage conversion circuit includes a resistor which receives the output current of the second gm amplifier and generates a predetermined voltage, and generates a conversion voltage corresponding to the operation current for functioning the active filter as a filter having a predetermined cut off frequency depending on a terminal voltage of the resistor.

18. The data write circuit according to claim 17, wherein the voltage-current conversion circuit includes a (+) input and a (−) input, and the current-voltage conversion circuit further includes a constant voltage circuit which generates a predetermined voltage to be added or subtracted to and from the terminal voltage and outputs between the (+) input and the (−) input of the voltage-current conversion circuit a voltage obtained by adding or subtracting the predetermined voltage with respect to the terminal voltage of the resistor as the conversion voltage.

19. The data write circuit according to claim 18, further comprising first and second capacitors, wherein the first gm amplifier is provided in a plurality of numbers, one of the plurality of numbers of the gm amplifiers and the first capacitor constitutes an integrating circuit, another of the plurality of numbers of the gm amplifiers and the second capacitor constitutes a differentiating circuit, the active filter is constituted by the integrating circuit and the differentiating circuit connected in cascade, the voltage-current conversion circuit includes a (+) input and a (−) input, and the current-voltage conversion circuit further includes a constant voltage circuit which generates a predetermined voltage to be added or subtracted to and from the terminal voltage and outputs between the (+) input and the (−) input of the voltage-current conversion circuit a voltage obtained by adding or subtracting the predetermined voltage with respect to the terminal voltage of the resistor as the conversion voltage.

20. A data reproducing circuit including an active filter having a first gm amplifier and a capacitor and a setting signal generation circuit which sets a cut off frequency of the active filter at a predetermined value by controlling an operation current of the first gm amplifier, wherein the setting signal generation circuit comprises a second gm amplifier equivalent to the first gm amplifier, a band gap power source which applies a constant voltage making use of a band gap voltage to an input of the second gm amplifier and a current-voltage conversion circuit which converts an output current of the second gm amplifier into a voltage, and wherein operation currents of the first and second gm amplifiers are controlled depending on the output voltage of the current-voltage conversion circuit.
